(19) United States
(12) Patent Application Publication
(10) Pub. No.: US 2013/0264555 A1
(43) Pub. Date: Oct. 10, 2013

(54) ORGANIC EL ELEMENT AND TRANSLUCENT SUBSTRATE

(71) Applicant: Asahi Glass Company, Limited, Tokyo (JP)

(72) Inventors: Nao Ishibashi, Tokyo (JP); Nobuhiro Nakamura, Tokyo (JP); Minoru Sekine, Tokyo (JP); Hisao Inokuma, Tokyo (JP); Yumiko Aoki, Tokyo (JP)

(21) Appl. No.: 13/901,929

(22) Filed: May 24, 2013

Related U.S. Application Data
(63) Continuation of application No. PCT/JP2011/078106, filed on Dec. 5, 2011.

(30) Foreign Application Priority Data
Dec. 20, 2010 (JP) 2010-283707

(51) Int. Cl. H01L 51/52; G02B 5/02

(52) U.S. Cl. CPC H01L 51/5268; G02B 5/0231
USPC 257/40; 428/172

(57) ABSTRACT

A translucent substrate may include a transparent support substrate, and a light extracting layer formed on the transparent support substrate, including a glass material having a first refractive index in a range of 1.6 to 2.2 for D line, and a scattering material having a second refractive index different from the first refractive index for the D line. The light extracting layer may have a surface formed with a plurality of projections including at least one of an approximately pyramid-shaped projection having one peak point and an approximately triangular prism-shaped projection having one peak edge. An inclination angle formed by an edge and a base edge of an approximate triangle, obtained in a vertical cross section passing through the peak point or the peak edge of the projection, may be in a range of 10° to 60°.

### CROSS-REFERENCE TO RELATED APPLICATIONS

This application is a continuation application filed under 35 U.S.C. 111(a) claiming the benefit under 35 U.S.C. 120 and 365(c) of a PCT International Application No. PCT/JP2011/078106 filed on Dec. 5, 2011, which is based upon and claims the benefit of priority of the prior Japanese Patent Application No. 2010-283707 filed on Dec. 20, 2010, the entire contents of which are incorporated herein by reference.

### BACKGROUND OF THE INVENTION

1. Field of the Invention

The present invention relates to an organic EL element.

2. Description of the Related Art

The organic EL (Electro-Luminescence) element is popularly used in displays, backlights, illumination purposes, and the like.

A general organic EL element may include a first electrode (or anode) provided on a support substrate, a second electrode (or cathode), and an organic light emitting layer provided between these electrodes. When a voltage is applied across the electrodes, holes and electrons are injected into the organic light emitting layer from the respective electrodes. Binding energy is generated when the holes and the electrodes recombine within the organic light emitting layer, and a light emitting material within the organic light emitting layer is excited by this binding energy. Light emission occurs when the excited light emitting material returns to a ground state, and the EL (Electro-Luminescence) element utilizes this phenomenon.

In many cases, a transparent thin film made of ITO (Indium Tin Oxide) or the like may be used for the first electrode, that is, the anode, and a metal thin film made of aluminum, silver, or the like may be used for the second electrode, that is, the cathode.

Recently, a proposal has been made to provide a light extracting layer made of a resin between the first electrode and the support substrate. For example, by providing the light extracting layer made of the resin and having a periodic concavo-convex pattern between the first electrode and the support substrate, the effect of extracting the light generated in the organic layer to the outside may be improved. An example of the light extracting layer is proposed in a Japanese Laid-Open Patent Publication No. 2009-9861.

In addition, a method of improving the light extraction efficiency by including a scattering material within the light extracting layer is proposed in an International Publication No. WO2009/017035.

However, the following problems may occur when the light extracting layer is formed by the resin.

First, the resin used for the light extracting layer has hygroscopic properties in many cases. For this reason, when the light extracting layer made of the resin is used for a long period of time, the light extracting layer may deteriorate and may become colored. When the deterioration or coloring occurs in the light extracting layer, the luminous efficacy of the organic EL element may deteriorate.

Second, the light extracting layer needs to have a high refractive index in many cases. This is because the refractive index of the anode (or ITO electrode) is relatively high, and total reflection may occur at an interface between the anode and the light extracting layer when the light extracting layer used has a low refractive index. However, it may be difficult to form a light extracting layer having a high refractive index from a resin.

Accordingly, the conventional light extracting layer made of the resin may suffer problems from the point of view of withstanding environmental conditions and obtaining a high refractive index.

The Japanese Laid-Open Patent Publication No. 2009-9861 described above proposes the light extracting layer made of the resin and having the periodic concavo-convex pattern. However, the Japanese Laid-Open Patent Publication No. 2009-9861 is silent on how the concavo-convex pattern should actually be configured in order to obtain a sufficiently high light extraction efficiency, and there is no disclosure related to an optimum concavo-convex pattern.

In addition, even when the scattering material is included in the light extracting layer as proposed in the International Publication No. WO2009/017035 described above, there is a limit to an amount of the scattering material that may be included in the light extracting layer in order to improve the light extraction efficiency.

### SUMMARY OF THE INVENTION

Accordingly, embodiments of the present invention may provide an organic EL element having a satisfactory light extraction efficiency. The EL element may include a light extracting layer that may withstand environmental conditions and obtain a high refractive index. Embodiments of the present invention may also provide a translucent substrate that may be used in such an organic EL element.

According to one aspect of the present invention, a translucent substrate may include a transparent support substrate; and a light extracting layer formed on the transparent support substrate, including a glass material having a first refractive index in a range of 1.6 to 2.2 for D line, and a scattering material having a second refractive index different from the first refractive index for the D line, wherein the light extracting layer includes a surface formed with a plurality of projections, the plurality of projections include at least one of an approximately pyramid-shaped projection having one peak point and an approximately triangular prism-shaped projection having one peak edge, and an inclination angle formed by an edge and a base edge of an approximate triangle, obtained in a vertical cross section passing through the peak point or the peak edge of the projection, is in a range of 10° to 60°.

In this translucent substrate the scattering material may be selected from a group consisting of pores, precipitation crystals, glass material particles different from those of the glass material, and phase-separated glass.

According to another aspect of the present invention, a translucent substrate may include a transparent support substrate; and a light extracting layer formed on the transparent support substrate, including a glass material having a first refractive index in a range of 1.6 to 2.2 for D line, and substantially no scattering material having a second refractive index different from the first refractive index for the D line, wherein the light extracting layer includes a surface formed with a plurality of projections, the plurality of projections include at least one of an approximately pyramid-shaped projection having one peak point and an approximately triangular prism-shaped projection having one peak edge, and an inclination angle ø formed by an edge and a base edge of an approximate triangle, obtained in a vertical cross section passing through the peak point or the peak edge of the projection, is in a range of 5° to 70°.

In this translucent substrate, the scattering material may include precipitation crystals of glass forming at least one of pores and the glass material.

In the above described translucent substrate, the inclination angle ø may be in a range of 15° to 40°.

In the above described translucent substrate, the plurality of projections may be arranged at random in a case in which dimensions of the base edge are within a range of 0.1 μm to 100 μm.

In the above described translucent substrate, the plurality of projections may be arranged periodically in a case in which dimensions of the base edge are outside a range of 0.1 μm to 100 μm.

According to still another aspect of the present invention, an organic EL (Electro-Luminescence) element may include the above described translucent substrate; a first electrode formed on the light extracting layer; an organic light emitting layer formed on the first electrode; and a second electrode formed on the organic light emitting layer.

### BRIEF DESCRIPTION OF THE DRAWINGS

FIG. 1 is a cross sectional view schematically illustrating an example of a conventional organic EL element;

FIG. 2A is a cross sectional view schematically illustrating an example of an organic EL element in an embodiment of the present invention;

FIG. 2B is a cross sectional view schematically illustrating another example of the organic EL element in the embodiment of the present invention;

FIG. 3 is a diagram illustrating an example of a periodic pattern of projections 140 on a surface of a light extracting layer 120, used in simulation;

FIG. 4 is a diagram illustrating another example of the periodic pattern of the projections 140 on the surface of the light extracting layer 120, used in simulation;

FIG. 5 is a diagram illustrating still another example of the periodic pattern of projections 140 on the surface of the light extracting layer 120, used in simulation;

FIG. 6 is a diagram illustrating still another example of the periodic pattern of projections 140 on the surface of the light extracting layer 120, used in simulation;

FIG. 7 is a diagram illustrating still another example of the periodic pattern of projections 140 on the surface of the light extracting layer 120, used in simulation;

FIG. 8 is a diagram illustrating a cross sectional structure of the organic EL element used in simulation;

FIG. 9 is a graph illustrating a relationship between an inclination angle of the projections and a light extracting amount;

FIG. 10 is a graph illustrating the relationship between the inclination angle of the projections and the light extracting amount, for a case in which a scattering material is dispersed in a second layer;

FIG. 11 is a graph illustrating a relationship between an area of a part on a scattering layer not formed with the projection and the light extracting amount;

FIG. 12 is a graph illustrating a relationship between the area of the part of the scattering layer not formed with the projection and the light extracting amount, for a case in which the inclination angle of the projections is 30° and the scattering material is dispersed in the second layer; and

FIG. 13 is a graph illustrating a relationship between the area of the part of the scattering layer not formed with the projection and the light extracting amount, for a case in which the inclination angle of the projections is 5° and the scattering material is dispersed in the second layer.

### DESCRIPTION OF THE PREFERRED EMBODIMENTS

A description will be given of the embodiments of the present invention, by referring to the drawings.

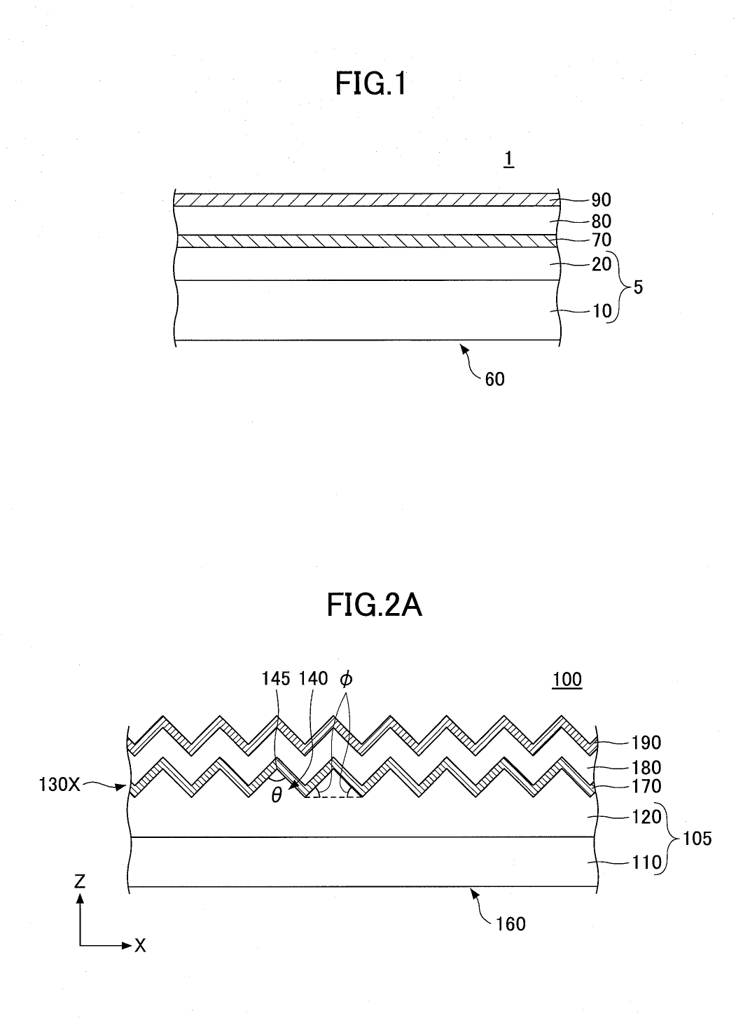

First, in order to facilitate understanding of features of the embodiments of the present invention, a brief description will be given of a configuration of an example of a conventional organic EL element, by referring to FIG. 1.

FIG. 1 is a cross sectional view schematically illustrating the example of the conventional organic EL element.

As illustrated in FIG. 1, a conventional organic EL element 1 may include a translucent substrate 5, a first electrode (or anode) 70, an organic light emitting layer 80, and a second electrode (or cathode) 90 that are stacked in this order. The translucent substrate 5 may be formed by stacking a light extracting layer 20 on a support substrate 10. In the example illustrated in FIG. 1, a lower surface of the organic EL element 1, that is, an exposed surface of the support substrate 10, forms a light extracting surface 60.

The light extracting layer 20 may have a function of scattering incident light in a plurality of directions. Accordingly, the organic EL element 1 provided with the light extracting layer 20 may suppress attenuation of light emitted from the light extracting layer 80, and compared to the configuration in which no light extracting layer 80 is provided, an amount of light emitted from the light extracting surface 60 may be improved.

The light extracting layer 20 of the conventional organic EL element 1 is made of a resin.

However, the following problems may occur in the case of the light extracting layer 20 that is made of the resin.

First, the resin used for the light extracting layer 20 has hygroscopic properties in many cases. For this reason, when the light extracting layer 20 made of the resin is used for a long period of time, the light extracting layer 20 may deteriorate and may become colored. When the deterioration or coloring occurs in the light extracting layer 20, the luminous efficacy of the organic EL element 1 may deteriorate.

Second, the light extracting layer 20 needs to have a high refractive index in many cases. This is because the refractive index of the first electrode (or anode) 70, made of ITO in many cases, is relatively high, and total reflection may occur at an interface between the first electrode 70 and the light extracting layer 20 when the light extracting layer 20 used has a low refractive index. However, it may be difficult to form a light extracting layer having a high refractive index from a resin. In many cases, a refractive index n_{d} of the resin is on the order of 1.4 to 1.6.

Accordingly, the conventional light extracting layer 20 made of the resin may suffer problems from the point of view of withstanding environmental conditions and obtaining a high refractive index.

On the other hand, according to one feature in an embodiment of the present invention, the light extracting layer may be made of glass having a relatively high refractive index.

Compared to the resin, the glass is superior from the point of view of withstanding environmental conditions, and deteriorations are unlikely to occur even after the glass is used for a long period of time. In addition, the glass that is used for the light extracting layer in the embodiment of the present invention may have a refractive index n_{d} in a range of 1.6 to 2.2. When the light extracting layer has such a high refractive index, the problem of the light reflecting at the interface between the light extracting layer and the first electrode (or anode) may be suppressed.

In addition, according to another feature in an embodiment of the present invention, a periodic pattern of approximately pyramid-shaped projections or approximately triangular prism-shaped projections may be formed on a surface of the light extracting layer.

As will be described hereunder, in an organic EL element having such a light extracting layer, light generated in the organic EL element may be extracted to the outside with a high light extraction efficiency.

The Japanese Laid-Open Patent Publication No. 2009-9861 described above proposes the light extracting layer made of the resin and having the periodic concavo-convex pattern. However, the Japanese Laid-Open Patent Publication No. 2009-9861 is silent on how the concavo-convex pattern should actually be configured in order to obtain a sufficiently high light extraction efficiency, and there is no disclosure related to an optimum concavo-convex pattern.

On the other hand, as will be described hereunder, the present inventors considered various patterns and repeated such considerations, and found for the first time that a satisfactory light extraction efficiency is obtainable when the surface of the light extracting layer falls under one of the following cases (i) and (ii).

In the case (i), the surface of the light extracting layer has a periodic pattern of approximately pyramid-shaped projections having one “peak point” and an “inclination angle” in a range of 5° to 70°.

In this specification, the term “peak point” refers to a vertex that is farthest away from an interface between the light extracting layer and the support substrate, amongst all vertexes of the pyramid. For example, in the case of a pyramid other than a triangular pyramid (or tetrahedron), a largest number of edges extend from the “peak point”. On the other hand, in the case of the triangular pyramid, the number of edges extending from each vertex is three. In the following description, the interface between the light extracting layer and the support substrate may also be simply referred to as the “interface”.

In addition, the term “inclination angle” refers to either one of two angles respectively formed by a base edge of an approximate triangle that is obtained in a vertical cross section passing through the “peak point” of the projection, and an edge of the approximate triangle passing through the “peak point” of the projection. The term “approximate triangle” refers not only to triangles whose vertexes are acute angles, but also to triangles whose vertexes are rounded during a fabrication process.

In the case (ii), the surface of the light extracting layer includes a periodic pattern of approximately triangular prism-shaped projections having one “peak edge” and an “inclination angle” in a range of 5° to 70°.

In this specification, the term “peak edge” refers to an edge that is farthest away from the “interface”, amongst all edges of the approximately triangular prism extending in an axial direction of the approximately triangular prism.

In addition, the term “inclination angle” refers to a larger one of two angles respectively formed by a base edge of an approximate triangle that is obtained in a vertical cross section passing through the “peak edge” of the projection, and an edge of the approximate triangle passing through a vertex of the approximate triangle.

In other words, in an embodiment of the present invention, the periodic or non-periodic pattern of approximately pyramid-shaped projections having one peak point, or the periodic or non-periodic pattern of approximately triangular prism-shaped projections having one peak edge, is formed on the surface of the light extracting layer. In addition, at least one angle formed between the base edge of the approximate triangle obtained in the vertical cross section passing through the peak point of the projection and another edge of the approximate triangle, or between the base edge of the approximate triangle obtained in the vertical cross section passing through the peak edge of the projection and another edge of the approximate triangle, is in a range of 5° to 70°.

According to this configuration of the light extracting layer, the EL element in accordance with an embodiment of the present invention may satisfactorily withstand environmental conditions and obtain a significantly higher refractive index when compared to the conventional EL element.

In the description given heretofore, the “inclination angle” is defined for the cases in which the peak point or the peak edge of the projection are clearly observed.

However, the “inclination angle” may be obtained in the following manner even in a case in which the peak point or the peak edge of the projection is unclear, such as when each side or each surface defining the projection is non-linear or curved, for example. In other words, in the case (i), the “peak point” may be determined by linearly extrapolating a plurality of edge lines of the projection and obtaining an intersection of the extrapolated edge lines. In addition, in the case (i), the inclination angle may be determined based on the approximate triangle obtained in the vertical cross section passing through the “peak point” that is determined in this manner, and the edges passing through the “peak point” of the obtained approximate triangle may be linearly extrapolated if necessary. Similarly, in the case (ii), the “peak edge” of the projection may be determined by linearly extrapolating sloping (or inclined) surfaces of the projection and obtaining an intersection of the extrapolated sloping surfaces. Further, in the case (ii), the inclination angle may be determined based on the approximate triangle obtained in the vertical cross section passing through the “peak edge” that is determined in this manner, and the sloping surfaces passing through the vertex of the obtained approximate triangle may be linearly extrapolated if necessary.

(Configuration of Organic EL Element in Embodiment of Present Invention)

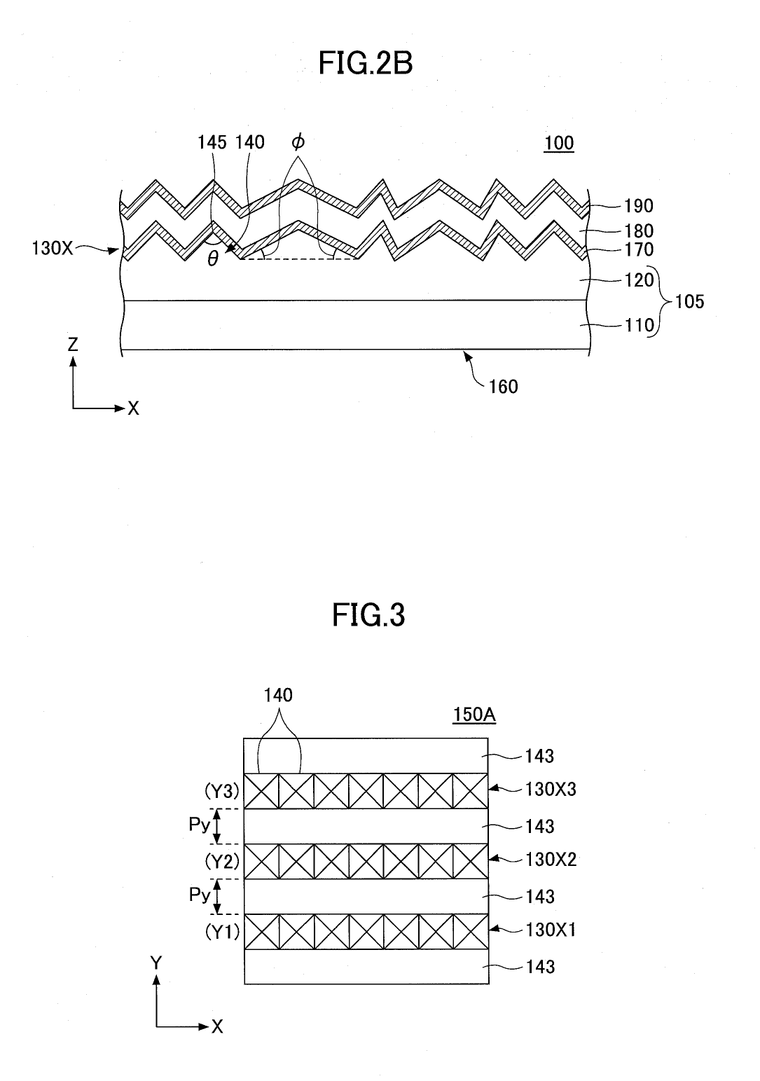

Next, a more detailed description will be given of the configuration of the organic EL element in an embodiment of the present invention, by referring to FIGS. 2A and 2B.

FIGS. 2A and 2B schematically illustrate cross sections of examples of a part of the organic EL element in an embodiment of the present invention. FIG. 2A is a cross sectional view schematically illustrating a part of the organic EL element for a case in which the projections of the light extracting layer are periodically formed, and FIG. 2B is a cross sectional view schematically illustrating a part of the organic EL element for a case in which the projections of the light extracting layer are randomly formed and are non-periodic. As will be described later in mode detail, the configuration illustrated in FIG. 2B may be preferable in a case in which the dimensions of the base edge of the projection are within a range of 0.1 μm to 100 μm. On the other hand, the configuration illustrated in FIG. 2B may be used in a case in which the dimensions of the base edge of the projection are outside the range of 0.1 μm to 100 μm. According to the considerations made by the present inventors, in the case in which the dimensions of the base edge of the projection are within the range of 0.1 μm to 100 μm and the projections are periodically arranged, diffraction and interference of light may occur. When such diffraction and interference of light occur, light may appear to be iridescent in a white organic EL element, for example. For this reason, in the case in which the dimensions of the base edge of the projection are within the range of 0.1 μm to 100 μm, the projections may preferably have a non-periodic arrangement. However, in a case in which a scattering material is dispersed within the light extracting layer, and in a case in which a film or the like having scattering properties is provided on an outer side of the organic EL element, the diffraction and interference of light may be reduced, and thus, the projections may have a periodic arrangement in such cases. On the other hand, in the case in which the dimensions of the base edge of the projection are outside the range of 0.1 μm to 100 μm, the interference of light does not occur even when the projections have the periodic arrangement, and in this case, the projections may either have the periodic arrangement or the non-periodic arrangement.

As illustrated in FIGS. 2A and 2B, an organic EL element 100 in an embodiment of the present invention may include a translucent substrate 105, a first electrode (or anode) 170, an organic light emitting layer 180, and a second electrode (or cathode) 190 that are stacked in this order. In the examples illustrated in FIGS. 2A and 2B, a lower surface of the organic EL element 100, that is, an exposed surface of the translucent substrate 105, forms a light extracting surface 160.

The first electrode 170 may be formed by a thin film of a transparent metal oxide, such as ITO (Indium Tin Oxide), for example. On the other hand, the second electrode 190 may be formed by a metal, such as aluminum and silver, for example. In this embodiment, the materials used for the first and second electrodes 170 and 190 are not limited to the materials described above, and other suitable materials may be used.

In many cases, the organic light emitting layer 180 may be formed by a plurality of layers such as an electron transport layer, an electron injecting layer, a hole transport layer, a hole injecting layer, and the like in addition to a light emitting layer.

The translucent substrate 105 may be formed by a transparent support substrate 110, and a light extracting layer 120 provided on the transparent support substrate 110. The light extracting layer 120 may have a function of scattering incident light, and reducing reflection of light at an interface between the light extracting layer 120 and a layer adjacent to the light extracting layer 120.

As described above, the light extracting layer 120 in this embodiment is made of a glass material having the refractive index n_{d} in a range of 1.6 to 2.2. In addition, approximately pyramid-shaped projections 140 respectively having one peak point 145 are formed on the surface of the light extracting layer 120 with a periodic pattern or a non-periodic pattern. Moreover, the glass material used for the light extracting layer 120 may have a refractive index n_{d} in a range of 1.7 to 2.2. In this specification, the refractive index n_{d} refers to the refractive index for the D line having a wavelength of 587.56 nm.

In FIGS. 2A and 2B, an inclination angle ø of the projection 140, that is, the angle formed between the base edge of the approximate triangle obtained in the vertical cross section passing through the peak point 145 of the projection 140, and the edge passing through the peak point 145, may be in a range of 5° to 70°, and preferably in a range of 5° to 60°, and more preferably in a range of 15° to 40°. A satisfactory light extraction efficiency may be obtained in such angle ranges.

In the case in which the dimensions of the base edge of the projection 140 are within the range of 0.1 μm to 100 μm, the projections 140 may preferably have the non-periodic or random arrangement. However, in the case in which a scattering material is dispersed within the light extracting layer 120, and in the case in which a film or the like having scattering properties is provided on the outer side of the organic EL element 100, the diffraction and interference of light may be reduced, and thus, the projections 140 may have the periodic arrangement in such cases. On the other hand, in the case in which the dimensions of the base edge of the projection 140 are outside the range of 0.1 μm to 100 μm, the projections 140 may have the periodic arrangement.

In the examples illustrated in FIGS. 2A and 2B, each of the parts stacked on the light extracting layer 120, that is, each of the first electrode 170, the organic light emitting layer 180, and the second electrode 190, may have a surface shape corresponding to the surface pattern of the light extracting layer 120. For example, when the organic EL element 100 is viewed from above the organic EL element 100, the second electrode 190 has the concavo-convex shape.

In the example illustrated in FIG. 2A, the dimensions of the base edge of the projection 140 of the light extracting layer 120 are outside the range of 0.1 μm to 100 μm. In this case, the pattern of the light extracting layer 120 includes a repetition row 130X in which the projections 140 having the approximately triangular cross section are repeated in an X-direction. The repetition row 130X may be similarly arranged at different coordinates (for example, Y1, Y2, . . . ) in a Y-direction. In other words, a plurality of repetition rows 130X may be arranged in a two-dimensional XY plane, as illustrated in FIG. 3, for example.

Other variations of the pattern of the light extracting layer 120 are possible in addition to the patterns described above.

FIGS. 3 through 6 illustrate examples of the pattern of the projections 140 of the light extracting layer 120, used in simulation. FIGS. 3 through 6 are schematic plan views that are viewed from above the light extracting layer 120. In addition, it is assumed in FIGS. 3 through 6 that each projection 140 has a square pyramid shape, and an intersection of two linear edges of the square pyramid is a peak point of the square pyramid.

In a periodic pattern 150A illustrated in FIG. 3, each of the square pyramid-shaped projections 140 are arranged along the X-direction at different Y coordinates Y1, Y2, and Y3. In other words, a repetition row 130X1 is formed at the Y coordinate Y1, a repetition row 130X2 is formed at the Y coordinate Y2, and a repetition row 130X3 is formed at the Y coordinate Y3. A horizontal region 143 that is approximately flat (or planar) is formed in regions of the periodic pattern 150A where no projection 140 is provided.

A pitch (or interval) Py of each of the repetition rows 130X in the Y-direction is not limited to a particular pitch. In the example illustrated in FIG. 3, the pitch Py is equal to a length of one base edge of the projection 140. The pitch Py between the Y-coordinates Y1 and Y2, and the pitch Py between the Y-coordinates Y2 and Y3 may be the same or may be different.

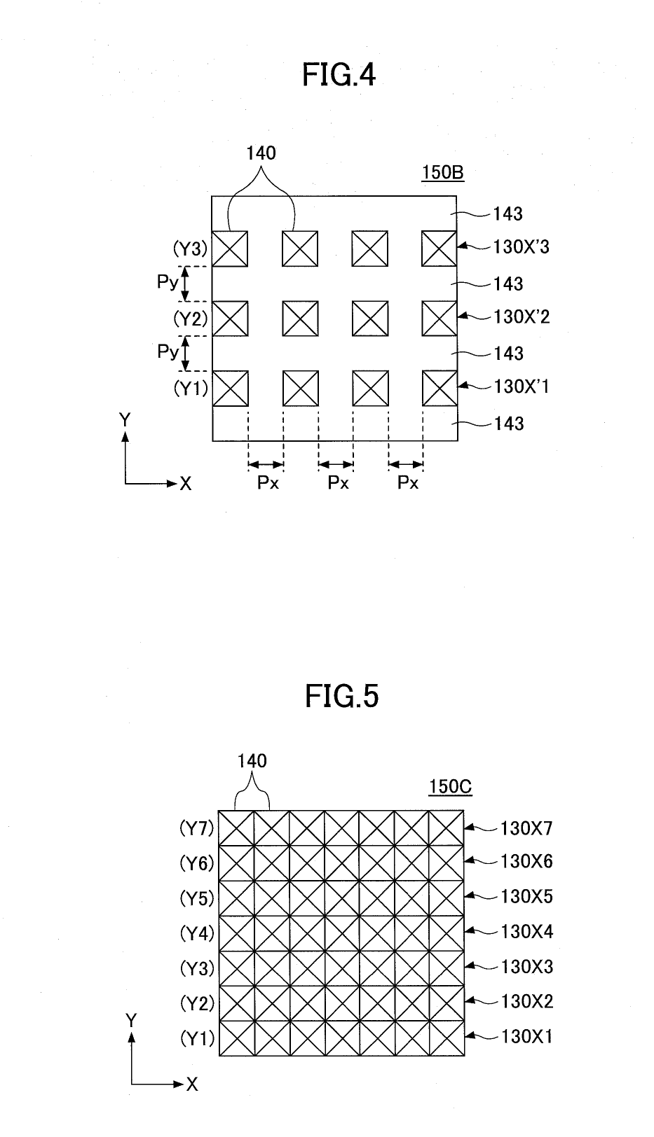

On the other hand, in the case of a periodic pattern 150 illustrated in FIG. 4, repetition rows 130X′, namely, repetition rows 130X′1, 130X′2, and 130X′3, are arranged in place of the repetition rows 130X illustrated in FIG. 3. The projections 140 of the repetition rows 130X′ are discontinuously arranged along the X-direction. For example, in the example illustrated in FIG. 4, each of the projections 140 is separated by a pitch Px from an adjacent projection 140 in each of the repetition rows 130X′. The pitch Px may be the same as the pitch Py, or may be different from the pitch Py.

In addition, in the case of a periodic pattern 150C illustrated in FIG. 5, the repetition rows 130X in FIG. 3 are repeatedly arranged in the Y-direction without a gap, that is, without forming the horizontal regions 143. In other words, the periodic pattern 150C illustrated in FIG. 5 corresponds to a case in which the pitch Px=0 in the periodic pattern 150A illustrated in FIG. 3.

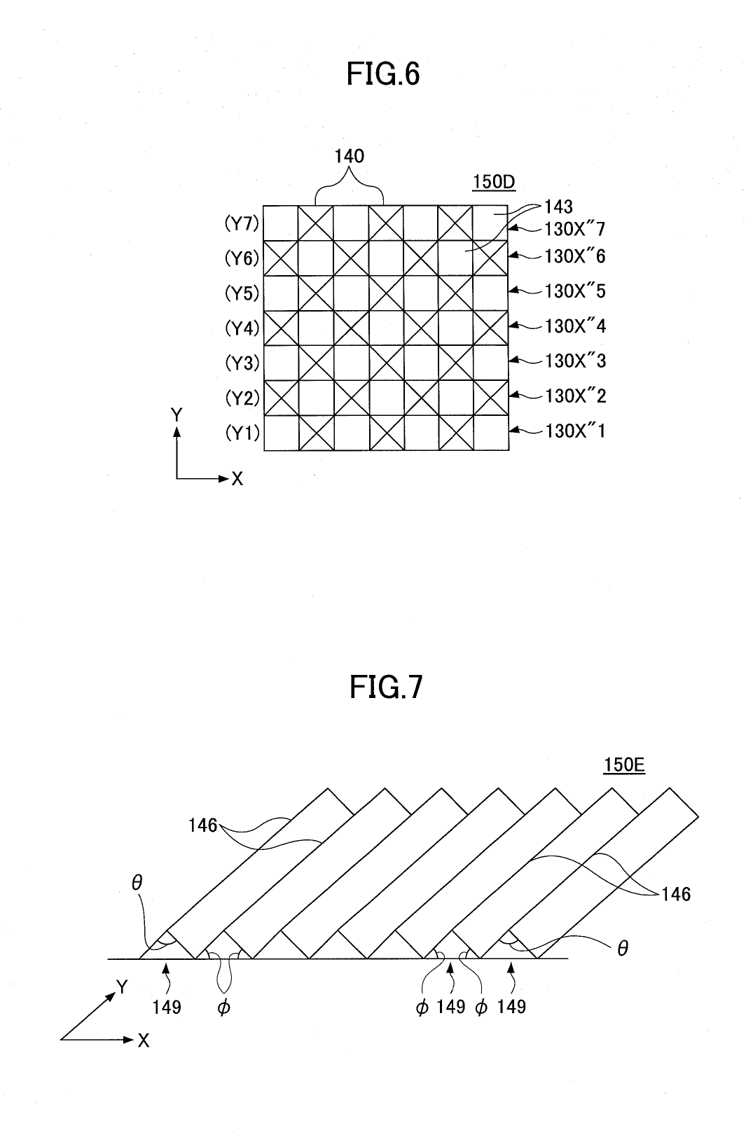

Furthermore, in the case of a periodic pattern 150D illustrated in FIG. 6, the projections 140 of the periodic pattern 150C in FIG. 5 are removed in a checker-board pattern, and the horizontal region 143 is formed in regions where no projection 140 is provided.

The periodic pattern 150D may be regarded as a pattern in which a repetition row 130X″1 and a repetition row 130X″2 are alternately arranged in the Y-direction. In FIG. 6, each of the repetition rows 130X″ are not separated in the Y-direction, however, each of the repetition rows 130X″ may be separated by the pitch Py in the Y-direction.

In the periodic patterns described above, it is assumed for the sake of convenience that each projection 140 has the square pyramid shape. However, the shape of each projection 140 is not limited to the square pyramid shape, and the shape may be any pyramid such as a triangular pyramid (or tetrahedron), rectangular (or quadrilateral) pyramid, hexagonal pyramid, and the like, for example.

In the examples described above, each projection 140 has the same base edge dimensions in both the X-direction and the Y-direction because the projection 140 has the square pyramid shape. However, each projection 140 may have different base edge dimension in the X-direction and the Y-direction.

For example, as illustrated in FIG. 7, each projection 149 may have a triangular prism shape having a longitudinal axis thereof extending along one direction.

In a periodic pattern 150E illustrated in FIG. 7, each of the projections 149 has a peak edge 146 extending along the Y-direction, and the projections 149 are arranged along the X-direction.

In the case of the periodic pattern 150E, the above described effects of the embodiment may be obtained when an angle ø formed between a base edge and another edge of the approximate triangle obtained in the vertical cross section with respect to the peak edge 146 of the projection 149 is in a range of 5° to 70°.

Of course, it may be obvious to those skilled in the art that other variations of the pattern of the light extracting layer 120 are possible in addition to the patterns described above.

For example, FIG. 2B illustrates the example in which the base edge of the projection 140 in the light extracting layer 120 is within the range of 0.1 μm to 100 μm. In this case, the projections 140 and 149 are arranged at random on the XY-plane in the pattern of the light extracting layer 120. For example, the pattern of the light extracting layer 120 may include the approximately pyramid-shaped projections 140 illustrated in FIGS. 3 through 6 and the approximately triangular prism-shaped projections 149 illustrated in FIG. 7 arranged at random. In addition, each of the projections 140 and each of the projections 149 may have different shapes.

The projections in the configuration of the embodiment described above are either the pyramid shaped projections 140 having the peak point or the triangular prism shaped projections 149 having the peak edge. However, it may be obvious to those skilled in the art that each of the projections 140 and 149 may have an approximately truncated pyramid shape. In this case, edges forming side surfaces of the truncated pyramid may be extrapolated, and an intersection of the extrapolated edges may be obtained, in order to obtain the peak point or the peak edge. In addition, the inclination angle may be obtained by assuming a vertical cross section passing through the imaginary (or virtual) peak point or a cross section perpendicular to the imaginary (or virtual) peak edge.

(Parts Included in Organic EL Element)

Next, a description will be given of parts forming the organic EL element in an embodiment of the present invention.

The support substrate 110 may be made of a transparent material, that is, a material having a high transmittance with respect to visible light. For example, the support substrate 110 may be a glass substrate or a plastic substrate.

The glass substrate may be made of a material such as alkali glass, or an inorganic glass such as no-alkali glass and silica glass. In addition, the plastic substrate may be made of a material such as polyester, polycarbonate, polyether, polysulfone, polyether sulfone, polyvinyl alcohol, and fluorine-containing polymers such as polyvinylidene fluoride and polyvinyl fluoride.

The thickness of the support substrate 110 is not limited to a particular thickness, and may be in a range of 0.1 mm to 2.0 mm, for example. When the strength and weight of the support substrate 110 are taken into consideration, the thickness of the support substrate 110 may preferably be in a range of 0.5 mm to 1.4 mm.

(Light Extracting Layer 120)

As described above, the light extracting layer 120 may be made of a glass material having a high refractive index, that is, a refractive index n_{d} in a range of 1.6 to 2.2. Examples of the glass material having such a refractive index may include soda-lime glass, borosilicate glass, no-alkali glass, silica glass, and the like, for example.

A plurality of scattering materials may be dispersed within the glass material. Examples of the scattering material may include pores (or bubbles), precipitation crystals, glass material particles different from those of the glass material that forms a matrix, phase-separated glass, and the like, for example. The phase-separated glass may refer to glass that is formed by two or more glass phases. A difference between the refractive index of the glass material that forms the matrix and the refractive index of the scattering material may be as large as possible.

In addition, the amount of scattering material within the light extracting layer 120 may decrease from an inner part thereof towards an outer side thereof. In this case, a high light extraction efficiency may be achieved by the light extracting layer 120.

The thickness of the light extracting layer 120 may be in a range of 5 μm to 50 μm, for example.

In the following description, “including substantially no scattering material” in the light extracting layer 120 refers to a case in which no scattering material is intentionally included within the light extracting layer 120. For this reason, when forming the light extracting layer 120 that includes substantially no scattering material from the glass material, pores (or bubbles), crystals, and the like that are naturally formed when forming the light extracting layer 120 itself may be included in the light extracting layer 120.

(First Electrode 130)

The first electrode 170 may require a translucence on the order of 80% or higher in order to enable extraction of the light emitted from the organic light emitting layer 180 to the outside. In addition, the first electrode 170 may require a large work function in order to inject a large number of holes.

The first electrode 170 may be made of a material such as ITO, SnO₂, ZnO, IZO (Indium Zinc Oxide), AZO (ZnO—Al₂O₃: zinc oxide doped with aluminum), GZO (ZnO—Ga₂O₃: zinc oxide doped with gallium), Nb-doped TiO₂, Ta-doped TiO₂, and the like, for example.

In many cases, the thickness of the first electrode 170 may be on the order of 50 nm to 1.0 μm.

The first electrode 170 may have a refractive index on the order of 1.9 to 2.2 For example, when ITO is used for the first electrode 170, the refractive index of the first electrode 170 may be reduced by increasing the carrier concentration. In the ITO that is commercially available, a standard may include 10 wt % of SnO₂, however, the refractive index of the ITO may be reduced by further increasing the Sn concentration. Although the carrier concentration may increase as the Sn concentration increases, the mobility and transmittance may decrease. Accordingly, the amount of Sn may be determined by taking into consideration the balance of the refractive index, the mobility, and the transmittance as a whole.

(Organic Light Emitting Layer 180)

The organic light emitting layer 180 may have a light emitting function. In many cases, the organic light emitting layer 180 may include a hole injecting layer, a hole transport layer, a light emitting layer, an electron transport layer, and an electron injecting layer. However, it may be obvious to those skilled in the art that not all of these layers are required in the organic light emitting layer 180 as long as the light emitting layer is provided. In many cases, the organic light emitting layer 180 may have a refractive index in a range of 1.7 to 1.8.

The hole injecting layer may preferably have an ionization potential whose difference from an ionization potential of the first electrode 170 is small, in order to lower the barrier with respect to the hole injection from the first electrode 170. When the charge injection efficiency from the first electrode 170 to the hole injecting layer increases, a driving voltage of the organic EL element 100 may decrease, to increase the charge injection efficiency of the organic EL element 100.

The hole injecting layer may be made of a material such as polymer materials and LMW (Low Molecular Weight) materials. The polymer materials may include polyethylenedioxythiophene doped with polystyrene sulfonic acid (PSS), or PEDOT:PSS. The LMW materials may include copper phthalocyanine (CuPc) of the phthalocyanine family.

The hole transport layer may have a function to transport holes injected from the hole injecting layer to the light emitting layer. The hole transport layer may be made of a material such as a triphenylamine derivative, N,N′-bis(1-naphthyl)-N,N′-diphenyl-1,1′-biphenyl-4,4′-diamine (NPD), N,N′-diphenyl-N,N′-bis[N-phenyl-N-(2-naphthyl)-4′-aminobiphenyl-4-yl]-1,1′-biphenyl-4,4′-diamine (NPTE), 1,1-bis[(di-4-tolylamino)phenyl]cyclohexane (HTM2), N,N′-diphenyl-N,N′-bis(3-methylphenyl)-1,1′-diphenyl-4,4′-diamine (TPD), and the like.

The thickness of the hole transport layer 112 may be in a range of 10 nm to 150 nm, for example. The thinner the hole transport layer, the lower the driving voltage of the organic EL element 100 may be. However, when the problem of short-circuiting between the electrodes is taken into consideration, the thickness of the hole transport layer in many cases may be in a range of 10 nm to 150 nm.

The light emitting layer may have a function to provide a region in which the injected electrons and holes may recombine. The light emitting layer may be made of an organic light emitting material, including polymer materials and LMW materials.

Examples of the material used for the light emitting layer may include metal complexes of quinoline derivatives such as a tris(8-quinolinolate)aluminum complex (Alq3), bis(8-hydroxy)quinaldine aluminum phenoxide (Alq′2OPh), bis(8-hydroxy)quinaldine aluminum 2,5-dimethylphenoxide (BAlq), a mono(2,2,6,6-tetra-methyl-3,5-heptanedionate)lithium complex (Liq), a mono(8-quinolinolate)sodium complex (Naq), a mono(2,2,6,6-tetramethyl-3,5-heptanedionate)lithium complex, a mono(2,2,6,6-tetramethyl-3,5-heptanedionate)sodium complex, a bis(8-quinolinolate)calcium complex (Caq2), and the like, and fluorescent substances such as tetraphenylbutadiene, phenylquinacridone (QD), anthracene, perylene, coronene, and the like.

The light emitting layer may use, as a host material, a quinolinolate complex, and preferably an aluminum complex having 8-quinolinol or a derivative thereof as a ligand.

The electron transport layer may have a function to transport holes injected from the second electrode 190. Examples of the material used for the electron transport layer may include a quinolinol aluminum complex (Alq3), an oxadiazole derivative (for example, 2,5-bis(1-naphthyl)-1,3,4-oxadiazole (BND), 2-(4-t-butyl-phenyl)-5-(4-biphenyl)-1,3,4-oxadiazole (PBD) or the like), a triazole derivative, a bathophenanthroline derivative, a silole derivative, and the like.

The electron injecting layer may be provided by forming a layer doped with an alkali metal, such as lithium (Li), cesium (Cs), and the like, at an interface between the electron injecting layer and the second electrode 190.

(Second Electrode 190)

The second electrode 190 may be made of a metal having a small work function or an alloy of such a metal. Examples of the material used for the second electrode 190 may include an alkali metal, an alkaline earth metal, a metal of group 3 in the periodic table, and the like. For example, the second electrode 190 may be made of aluminum (Al), magnesium (Mg), an alloy of Al or Mg, and the like.

In addition, the second electrode 190 may be made of a co-vapor-deposited film of Al and MgAg, a stacked electrode in which Al is vapor-deposited on a vapor-deposited thin film of lithium fluoride (LiF) or lithium oxide (Li₂O). Further, the second electrode 190 may be made of a stacked structure in which calcium (Ca) or barium (Ba) and aluminum (Al) are stacked.

### PRACTICAL EXAMPLES

Next, a description will be given of practical examples of the present invention.

(Simulation 1)

The effects of the surface shape of the light extracting layer on the light extraction efficiency of the organic EL element were evaluated by computer simulation 1.

The simulation 1 used light tracking software (Light Tools, Cybernet Systems Co., Ltd.), and the following model was created.

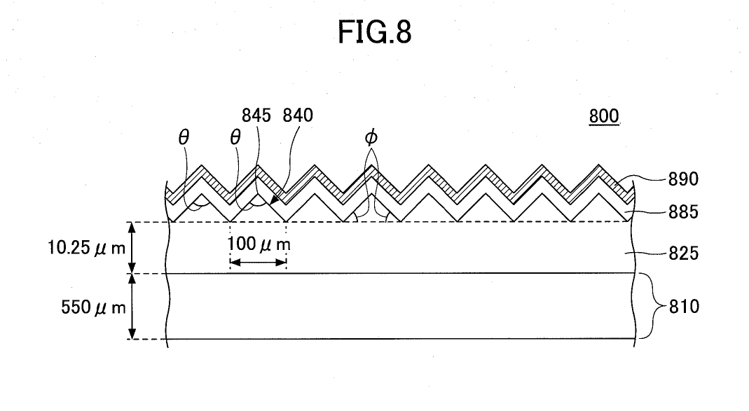

(1) In order to simplify the simulation 1, an organic EL element having a structure illustrated in FIG. 8 is used. That is, an organic EL element 800 used has a 4-layer structure including a first layer 810 having a refractive index of 1.55, a second layer 825 having a refractive index of 1.9, a third layer 995 having a refractive index of 1.9, and a fourth layer 890. When compared to the structure illustrated in FIG. 2, the first layer 810 corresponds to the support substrate 110, and the second layer 825 corresponds to a combination of the light extracting layer 120, the first electrode 170, and a lower half portion of the organic light emitting layer 180. In addition, the third layer 885 corresponds to an upper half portion of the organic light emitting layer 180, and the fourth layer 890 corresponds to the second electrode 190.

(2) An interface between the second layer 825 and the third layer 885 is regarded to be a light emitting surface, and the fourth layer 890 is regarded to be a reflection surface having a reflectance of 80% and an absorptance of 20%. Thicknesses of the light emitting surface and the reflection surface are assumed to be zero (0).

(3) The thickness of the first layer 810 is assumed to be 550 μm, and the thickness of the third layer 885 is assumed to be 0.03 μm. As illustrated in FIG. 8, the thickness of the second layer 825 may be represented by a sum of a 10.25 μm base portion to a bottom surface of a projection 840, and a height of the projection 840. However, the height of the projection 840 varies depending on an angle θ at the peak point 845. In addition, the length of the base edge of the projection 840 is assumed to be 100 μm and constant even through the angle θ at the peak point 845 may vary.

(4) The projection 840 is assumed to have a square pyramid shape, and it is assumed that the projections 840 are arranged with the pattern illustrated in FIG. 5.

The square pyramid-shaped projection 840 is used because the approximate triangle obtained in the vertical cross section passing through the peak point of the projection 840 becomes an isosceles triangle. In the case of the isosceles triangle, the angle formed between the base edge and one of the other two edges and the angle formed between the base edge and the other of the other two edges are the same. For this reason, a relationship between the light extracting amount and the angle between the base edge and the other edge of the approximate triangle may be simplified and be easier to comprehend. In actual practice, the two angles formed between the base edge and the other two edges of the approximate triangle may be different, and in such a case, it may be obvious that the light extracting amount may be determined depending on the two angles and a ratio of the lengths of the corresponding other edges of the approximate triangle. In other words, in the case of a triangle in which the inclination angles are 30° and 60°, the ratio of the lengths of the corresponding other edges is 1:√3. For example, when the light extracting amount in the case of the isosceles triangle having the inclination angle of 30° is denoted by A, and the light extracting amount in the case of the isosceles triangle having the inclination angle of 60° is denoted by B, the light extracting amount for the case of the triangle in which the inclination angles are 30° and 60° may be computed from (A+√3B)/(1+√3).

In the model described above, the angle θ at the peak point 845 is varied, and the light extracting amount OP, that is, the amount of light extracted from the lower side of the first layer 810, is calculated for the case in which light of 1 W is randomly emitted from the light emitting surface in a region having an area of 2 mm×2 mm in the organic EL element 800. The total number of rays emitted is assumed to be 100,000.

Because the projection 840 has the square pyramid shape, the shape of the vertical cross section becomes an isosceles triangle. In other words, the inclination angle may be represented by ø(°)=(180°−θ)/2.

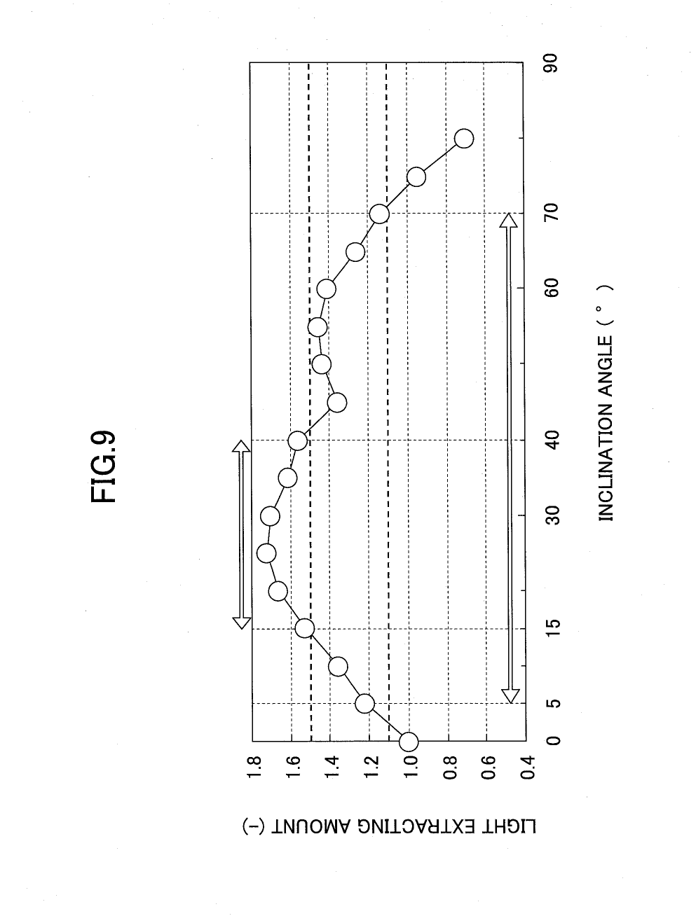

FIG. 9 illustrates a relationship between the inclination angle ø of the projections 840 of the second layer 825 and the light extracting amount, obtained by the simulation 1. In FIG. 9, the ordinate indicates a normalized light extracting amount which is obtained by normalizing the light extracting amount OP with reference to a reference light extracting amount OP₀ (1.0) for a case in which inclination angle ø is 0° (that is, there is no projection 840).

From the simulation results illustrated in FIG. 9, it may be observed that the normalized value of the light extracting amount exceeds 1.1 in a case in which the inclination angle ø is 5° to 70°. Particularly in a case in which the inclination angle ø is 15° to 40°, it may be observed that the normalized value of the light extracting amount exceeds 1.5, and that the light extracting amount OP increases by 1.5 times compared to the case in which the scattering layer includes no projections.

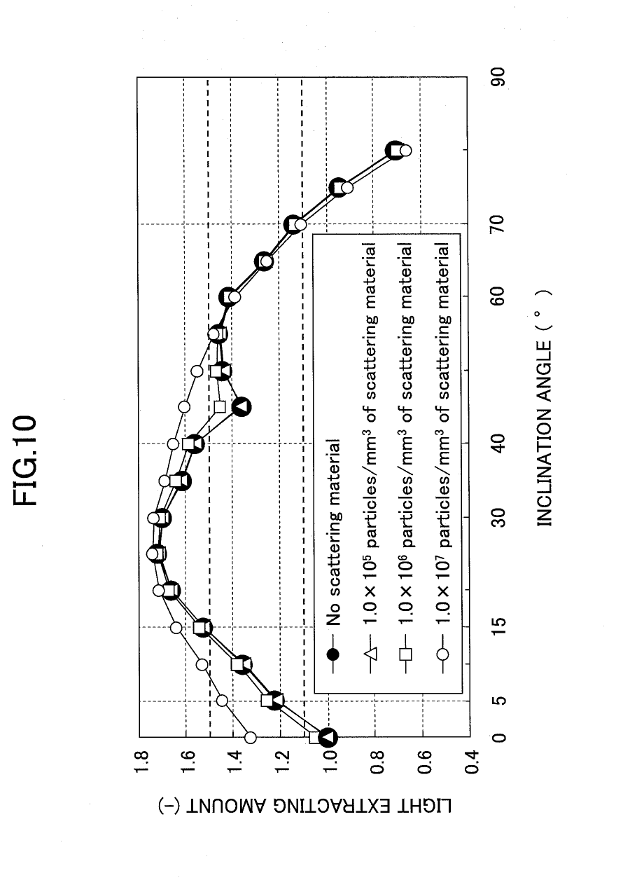

FIG. 10 illustrates the relationship between the inclination angle ø of the projections 840 of the second layer 825 and the light extracting amount, similarly obtained by the simulation 1, for a case in which the second layer 825 includes a scattering material having a particle radius of 0.5 μm and a refractive index of 1.0. For comparison purposes, FIG. 10 also illustrates the simulation results of FIG. 9 for the case in which the second layer 825 includes no scattering material. In FIG. 10, the ordinate indicates a normalized light extracting amount which is obtained by normalizing the light extracting amount OP with reference to the reference light extracting amount OP₀ for the case in which the second layer 825 includes no projections 840 and no scattering material.

FIG. 10 illustrates three cases in which the amount of scattering material added to the second layer 825 is 1.0×10⁵ particles/mm³, 1.0×10⁶ particles/mm³, and 1.0×10⁷ particles/mm³, respectively. It is assumed that the scattering material is dispersed throughout the entire second layer 825.

From the simulation results illustrated in FIG. 10, it may be found that the light extracting amount generally improves when the scattering material is added to the second layer 825. However, when the amount of scattering material added to the second layer 825 is 1.0×10⁶ particles/mm³ or less, the effect of improving the light extracting amount may not be notable. Accordingly, in order to further improve the light extracting amount by the addition of the scattering material to the second layer 825, it may be regarded that the amount of scattering material added to the second layer 825 may preferably be on the order of 1.0×10⁷ particles/mm³.

Therefore, it was confirmed that the light extracting amount of the organic EL element may be significantly improved by providing the projections on the surface of the light extracting layer and setting the inclination angle ø of the projections in a range of 5° to 70°.

(Simulation 2)

Next, computer simulation 2, similar to the simulation 1 described above, was performed for a case in which the projections 840 have the periodic pattern 150E illustrated in FIG. 7.

In this simulation 2, the height of the projection 840 is not varied and is maintained constant to 50 μm. In this case, an angle θ formed between a base edge of a triangle obtained in a cross section perpendicular to the peak edge of the projection 840 and the peak point 845 located at a position opposing the base edge is θ=120°. In addition, the inclination angle ø in this case is ø=30°.

The light extracting amount obtained by the simulation 2 is normalized by the value for the case in which no projection 840 is provided on the second layer 825, as described above.

According to the simulation results, the normalized value of the light extracting amount is 1.41. Therefore, it was confirmed that the light extracting amount of the organic EL element may be significantly improved by providing the projections on the surface of the light extracting layer, even with the periodic pattern illustrated in FIG. 7.

(Simulation 3)

Next, computer simulation 3, similar to the simulation 1 described above, was performed to study the effects of the ratio of the region provided with the projections 840 on the scattering layer and the region (that is, the horizontal region 143) not provided with the projections 840, on the light extracting amount.

The simulation 3 was performed for a case 1 in which the projections 840 have the periodic pattern 150C illustrated in FIG. 5, cases 2 and 3 in which the projections 840 have the periodic pattern 150B illustrated in FIG. 4, and cases 4, 6, and 7 in which the projections 840 have the period pattern 150A illustrated in FIG. 3, and a case 5 in which the projections 840 have the periodic pattern 150D illustrated in FIG. 6.

The height of the projection 840 is maintained constant to 50 μm for all of the cases 1 through 7. In addition, the inclination angle ø is assumed to be 30° and constant, that is, the vertex angle θ is assumed to be 120° and constant. Furthermore, the base edge of the projection 840 is assumed to have a constant length of 173.2 μm in both the X-direction and the Y-direction.

Moreover, in the cases 2 and 3, it is assumed that the pitch Px in the X-direction and the pitch Py in the Y-direction of the projections 840 are the same. In the case 2, the pitch Px (or Py) is set to 0.2 times the dimensions of the projection 840 in the X-direction (or Y-direction), and in the case 3, the pitch Px (or Py) is set to 0.5 times the dimensions of the projection 840 in the X-direction (or Y-direction). Further, in the case 4, the pitch Py of the projections 840 in the Y-direction is set the same as the dimensions of the projection 840 in the Y-direction. In the case 6, the pitch Px (or Py) is set to 2.0 times the dimensions of the projection 840 in the Y-direction. In the case 7, the pitch Px (or Py) is set to 3.0 times the dimensions of the projection 840 in the Y-direction.

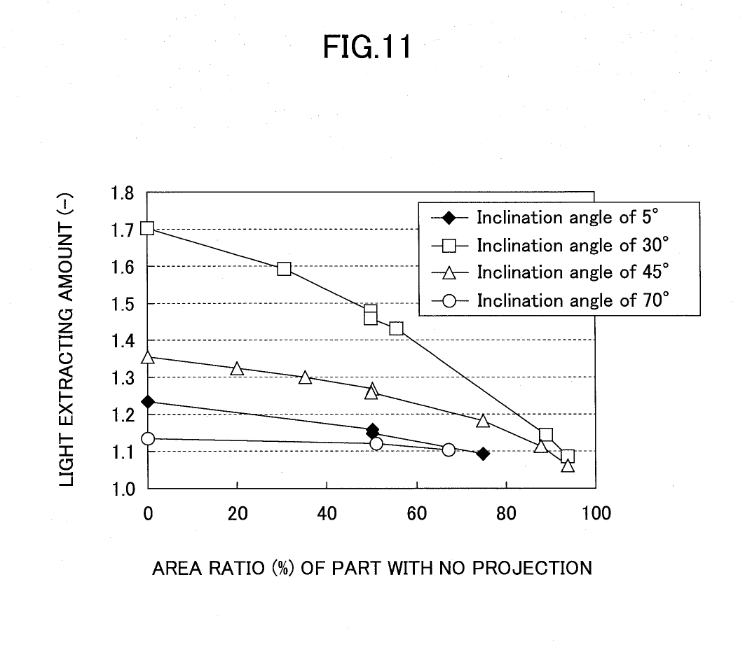

In addition, the simulation 3 is similarly performed for other cases in which the inclination angle of the projection 840 is 5°, 45°, and 70°, respectively, for different ratios of the horizontal region, and the simulation results illustrated in FIG. 11 are obtained.

In FIG. 11, the abscissa indicates a ratio of the area of the horizontal region at the surface of the scattering layer, with respect to the total area of the scattering layer. This ratio is the area ratio of the scattering layer not provided with the projection. For example, in the case 1, the ratio is zero (0). In addition, the ordinate indicates the light extracting amount obtained by the simulation 3. As described above, the ordinate indicates the normalized light extracting amount which is obtained by normalizing the light extracting amount OP with reference to the reference light extracting amount OP₀ for the case in which the second layer 825 includes no projections 840. From the simulation results, it may be observed that, as the horizontal region nor provided with the projection 840 decreases, the light extracting amount has a tendency of increasing.

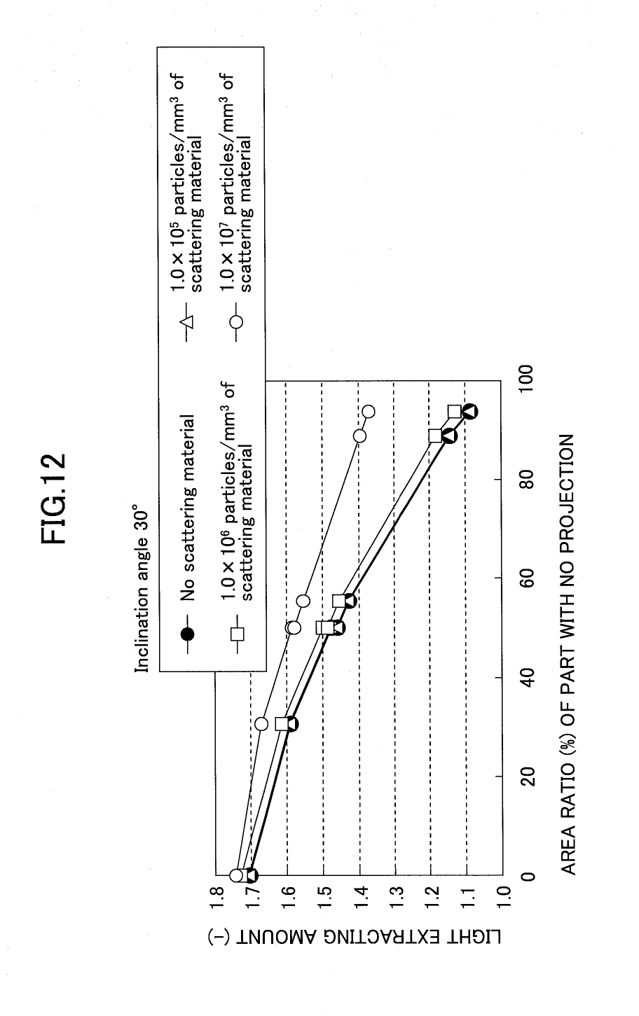

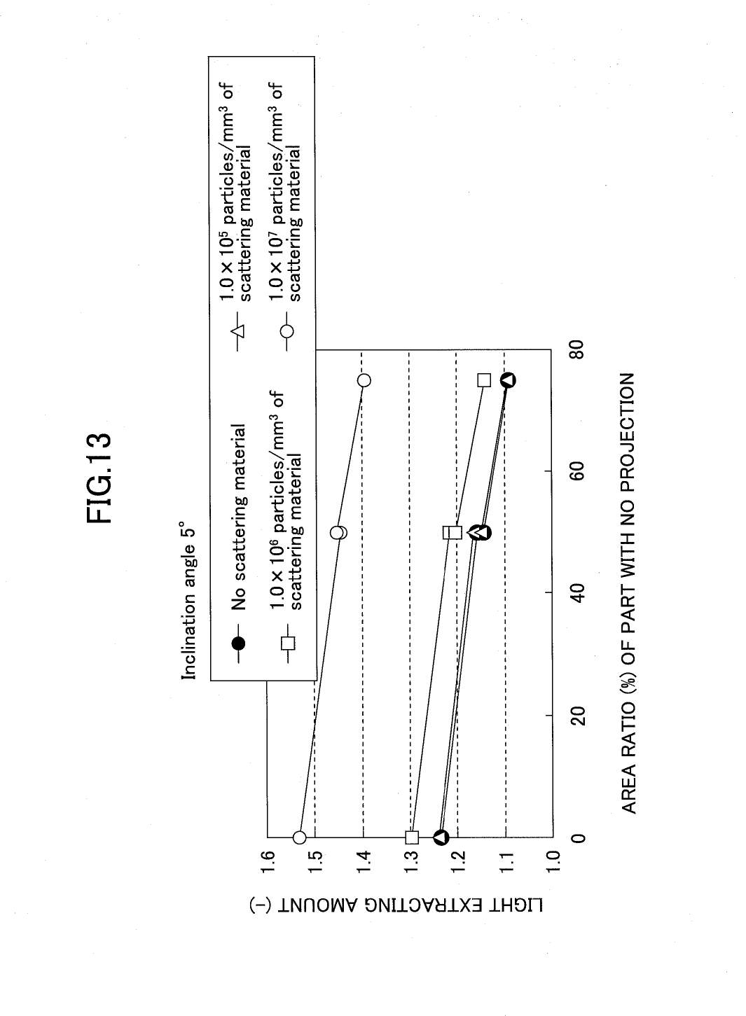

FIG. 12 illustrates similar simulation results for a case in which the inclination angle ø of the projection 840 is 30° and the scattering material dispersed in the second layer 825 has a refractive index of 1.0 and a particle diameter of 0.5 μm. Further, FIG. 13 illustrates similar simulation results for a case in which the inclination angle ø of the projection 840 is 30° and the scattering material dispersed in the second layer 825 has a refractive index of 1.0 and a particle diameter of 0.5 μm. In the graphs of FIGS. 12 and 13, the abscissa indicates the ratio of the area of the horizontal region at the surface of the scattering layer, with respect to the total area of the scattering layer. In addition, the ordinate indicates the light extracting amount obtained by the simulation 3. Similarly as in the case of FIG. 11, described above, the ordinate indicates the normalized light extracting amount which is obtained by normalizing the light extracting amount OP with reference to the reference light extracting amount OP₀ for the case in which the second layer 825 includes no projections 840. Each of FIGS. 12 and 13 illustrates three cases in which the amount of scattering material added to the second layer 825 is 1.0×10⁵ particles/mm³, 1.0×10⁶ particles/mm³, and 1.0×10⁷ particles/mm³, respectively. It is assumed that the scattering material is dispersed throughout the entire second layer 825. It may be observed from FIGS. 12 and 13 that the light extracting amount improves by the addition of the scattering material, and that the light extracting amount may be increased by adding the scattering material, even when the ratio of the scattering layer occupied by the horizontal region is relatively large.

According to the embodiment, the light extraction efficiency may be improved without having to include a large amount of scattering material in the light extracting layer. When the amount of added scattering material is large, the amount of scattering light not only towards the front but also towards the back increases. The front refers to a direction of the light extracting layer when viewed from the light emitting layer, and the back refers to a direction opposite to the direction of the light extracting layer when viewed from the light emitting layer. The light scattering towards the back may be reflected by a metal surface of the cathode when a metal material is used for the cathode, and the reflected scattering light may change traveling directions towards the front such that the light may be obtained outside the organic EL element. However, because the reflectance of the metal surface is not 100%, the amount of light always decreases. For example, when Al is used for the cathode, the reflectance of the Al surface is on the order of 80%, and approximately 20% of the light is lost. Accordingly, if the amount of added scattering material is excessively large, the loss of light occurs at the metal surface when the light is reflected, and there is a limit to improving the light extraction efficiency. In addition, although the extent of light absorption is small, the light absorption does occur in the light extracting layer, the transparent electrode, and the like. For this reason, when the amount of added scattering material is excessively large, the distance traveled by the light within such light absorbing layers increases considerably, and as a result, the amount of light obtained outside the organic EL element decreases due to the effects of the light absorbing layers. But according to the embodiment, the light extraction efficiency may be improved by providing the slope or projection on the light extracting layer, without having to increase the amount of added scattering material.

The embodiments of the present invention may be applied to organic EL elements and the like to be used in light emitting devices and the like.

The embodiments of the present invention may provide an organic EL element having a satisfactory light extraction efficiency. The EL element may include a light extracting layer that may withstand environmental conditions and obtain a high refractive index. The embodiments of the present invention may also provide a translucent substrate that may be used in such an organic EL element.

The EL element and the translucent substrate are described above with reference to the embodiments, however, it may be apparent to those skilled in the art that the present invention is not limited to the above embodiments, and various variations and modifications may be made without departing from the spirit and scope of the present invention.

What is claimed is:

1. A translucent substrate comprising:
a transparent support substrate; and
a light extracting layer formed on the transparent support substrate, including a glass material having a first refractive index in a range of 1.6 to 2.2 for D line, and a scattering material having a second refractive index different from the first refractive index for the D line,
wherein the light extracting layer includes a surface formed with a plurality of projections,
the plurality of projections include at least one of an approximately pyramid-shaped projection having one peak point and an approximately triangular prism-shaped projection having one peak edge, and
an inclination angle ø formed by an edge and a base edge of an approximate triangle, obtained in a vertical cross section passing through the peak point or the peak edge of the projection, is in a range of 10° to 60°.

2. The translucent substrate as claimed in claim 1, wherein the scattering material is selected from a group consisting of pores, precipitation crystals, glass material particles different from those of the glass material, and phase-separated glass.

3. The translucent substrate as claimed in claim 1, wherein the inclination angle ø is in a range of 15° to 40°.

4. The translucent substrate as claimed in claim 1, wherein the plurality of projections are arranged at random in a case in which dimensions of the base edge are within a range of 0.1 μm to 100 μm.

5. The translucent substrate as claimed in claim 1, wherein the plurality of projections are arranged periodically in a case in which dimensions of the base edge are outside a range of 0.1 μm to 100 μm.

6. An organic EL (Electro-Luminescence) element comprising:
a translucent substrate as claimed in claim 1;
a first electrode formed on the light extracting layer;
an organic light emitting layer formed on the first electrode; and
a second electrode formed on the organic light emitting layer.

7. A translucent substrate comprising:
a transparent support substrate; and
a light extracting layer formed on the transparent support substrate, including a glass material having a first refractive index in a range of 1.6 to 2.2 for D line, and substantially no scattering material having a second refractive index different from the first refractive index for the D line,
wherein the light extracting layer includes a surface formed with a plurality of projections,
the plurality of projections include at least one of an approximately pyramid-shaped projection having one peak point and an approximately triangular prism-shaped projection having one peak edge, and
an inclination angle ø formed by an edge and a base edge of an approximate triangle, obtained in a vertical cross section passing through the peak point or the peak edge of the projection, is in a range of 5° to 70°.

8. The translucent substrate as claimed in claim 7, wherein the scattering material includes precipitation crystals of glass forming at least one of pores and the glass material.

9. The translucent substrate as claimed in claim 7, wherein the inclination angle ø is in a range of 15° to 40°.

10. The translucent substrate as claimed in claim 7, wherein the plurality of projections are arranged at random in a case in which dimensions of the base edge are within a range of 0.1 μm to 100 μm.

11. The translucent substrate as claimed in claim 7, wherein the plurality of projections are arranged periodically in a case in which dimensions of the base edge are outside a range of 0.1 μm to 100 μm.

12. An organic EL (Electro-Luminescence) element comprising:
a translucent substrate as claimed in claim 7;
a first electrode formed on the light extracting layer;
an organic light emitting layer formed on the first electrode; and
a second electrode formed on the organic light emitting layer.
